(19) United States
(12) Patent Application Publication
(10) Pub. No.: US 2026/0186074 A1
(43) Pub. Date: Jul. 2, 2026

(54) EMERGENCY LIGHTING DEVICE HAVING AN EMERGENCY TEST FUNCTION

(71) Applicant: Xiamen PVTECH Co., Ltd., Xiamen (CN)

(72) Inventors: DEJIA LI, Xiamen (CN); CHUNMING LIU, Xiamen (CN); LIANGLIANG CAO, Xiamen (CN); FUXING LU, Xiamen (CN)

(21) Appl. No.: 19/428,348

(22) Filed: Dec. 22, 2025

(30) Foreign Application Priority Data
Dec. 26, 2024 (CN) 202411943271.0
Feb. 14, 2025 (CN) 202510166003.0

(51) Int. Cl. G01R 31/44; H02J 7/00; H02J 9/02; H05B 47/17

(52) U.S. Cl. CPC G01R 31/44; H02J 7/855; H02J 9/02; H05B 47/17

(57) ABSTRACT

An emergency lighting device having an emergency test function includes an emergency test switch, an input circuit, a processing circuit, an emergency circuit, and a load. The input circuit has a first pin, a second pin, a third pin, and a fourth pin. The first pin is connected to the live-wire output terminal of an external power source via a main switch. The second pin is connected to the live-wire output terminal. The third pin is connected to the neutral-wire output terminal of the external power source via the emergency test switch. The fourth pin is connected to the neutral-wire output terminal. The processing circuit is connected to the input circuit. The emergency circuit is connected to the processing circuit. The load is connected to the emergency circuit.

### TECHNICAL FIELD

The disclosure relates to lighting device, in particular to an emergency lighting device having an emergency test function.

### BACKGROUND

An emergency lighting device is a type of lighting apparatus that activates when the main lighting system fails due to incidents, and it is critically linked to building safety. Emergency lighting devices have been widely adopted in buildings such as security monitoring rooms, equipment rooms, large shopping malls, banks, hospitals, reading rooms, and similar spaces.

However, currently available emergency lighting devices still possess certain limitations. These devices lack effective emergency testing capabilities. The emergency test function serves as a key method to verify whether the emergency lighting device can activate properly when needed. Yet, current emergency lighting devices are unable to quickly and effectively check whether their emergency functions can operate correctly.

Therefore, it has become an important issue to develope an emergency lighting device with a reliable emergency test function.

### SUMMARY

One embodiment of the disclosure provides an emergency lighting device having an emergency test function includes an emergency test switch, an input circuit, a processing circuit, an emergency circuit, and a load. The input circuit has a first pin, a second pin, a third pin, and a fourth pin. The first pin is connected to the live-wire output terminal of an external power source via a main switch. The second pin is connected to the live-wire output terminal. The third pin is connected to the neutral-wire output terminal of the external power source via the emergency test switch. The fourth pin is connected to the neutral-wire output terminal. The processing circuit is connected to the input circuit. The emergency circuit is connected to the processing circuit. The load is connected to the emergency circuit.

Another embodiment of the disclosure provides an emergency lighting device having an emergency test function includes an emergency test switch, an input circuit, a processing circuit, an emergency circuit, and a load. The input circuit has a first pin, a second pin, a third pin, and a fourth pin. The first pin is connected to the live-wire output terminal of an external power source via a main switch. The second pin is connected to a neutral-wire output terminal of the external power source. The third pin is connected to the live-wire output terminal. The fourth pin is connected to the neutral-wire output terminal via the emergency test switch. The processing circuit is connected to the input circuit. The emergency circuit is connected to the processing circuit. The load is connected to the emergency circuit.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF DRAWINGS

The disclosure will become more fully understood from the detailed description given herein below and the accompanying drawings which are given by way of illustration only, and thus are not limitative of the disclosure and wherein:

FIG. 1 is a schematic view of an emergency lighting device having an emergency test function in accordance with a first embodiment of the disclosure.

FIG. 2 is a block diagram of a circuit structure of the emergency lighting device having the emergency test function in accordance with the first embodiment of the disclosure.

FIG. 3 is a block diagram of a circuit structure of an emergency lighting device having an emergency test function in accordance with a second embodiment of the disclosure.

FIG. 4 is a schematic view of an emergency lighting device having an emergency test function in accordance with a third embodiment of the disclosure.

FIG. 5 is a schematic view of an emergency lighting device having an emergency test function in accordance with a fourth embodiment of the disclosure.

FIG. 6 is a block diagram of a circuit structure of the emergency lighting device having the emergency test function in accordance with the fourth embodiment of the disclosure.

FIG. 7 is a schematic view of an emergency lighting device having an emergency test function in accordance with a fifth embodiment of the disclosure.

FIG. 8 is a side view of an emergency lighting device having an emergency test function in accordance with a sixth embodiment of the disclosure.

FIG. 9 is a first partial enlargement view of the emergency lighting device having the emergency test function in accordance with the sixth embodiment of the disclosure.

FIG. 10 is a second partial enlargement view of the emergency lighting device having the emergency test function in accordance with the sixth embodiment of the disclosure.

FIG. 11 is a third partial enlargement view of the emergency lighting device having the emergency test function in accordance with the sixth embodiment of the disclosure.

FIG. 12 is a fourth partial enlargement view of the emergency lighting device having the emergency test function in accordance with the sixth embodiment of the disclosure.

FIG. 13 is a schematic view of a load of the emergency lighting device having the emergency test function in accordance with the sixth embodiment of the disclosure.

FIG. 14 is a block diagram of a circuit structure of an emergency lighting device having an emergency test function in accordance with a seventh embodiment of the disclosure.

FIG. 15 is a partial enlargement view of the emergency lighting device having the emergency test function in accordance with the seventh embodiment of the disclosure.

FIG. 16A is a perspective view of an emergency circuit of the emergency lighting device having the emergency test function in accordance with the seventh embodiment of the disclosure.

FIG. 16B is a bottom view of the emergency circuit of the emergency lighting device having the emergency test function in accordance with the seventh embodiment of the disclosure.

FIG. 17A is a first side view of an emergency circuit of the emergency lighting device having the emergency test function in accordance with the seventh embodiment of the disclosure.

FIG. 17B is a second side view of the emergency circuit of the emergency lighting device having the emergency test function in accordance with the seventh embodiment of the disclosure.

FIG. 18 is a third side view of the emergency circuit of the emergency lighting device having the emergency test function in accordance with the seventh embodiment of the disclosure.

FIG. 19 is a perspective view of an emergency circuit of an emergency lighting device having an emergency test function in accordance with an eighth embodiment of the disclosure.

FIG. 20 is a block diagram of a circuit structure of a lighting device having an emergency lighting function in accordance with a ninth embodiment of the disclosure.

FIG. 21 is a block diagram of a circuit structure of a lighting device having an emergency lighting function in accordance with a tenth embodiment of the disclosure.

FIG. 22 is a block diagram of a circuit structure of a lighting device having an emergency lighting function in accordance with an eleventh embodiment of the disclosure.

FIG. 23 is a first schematic view of a square wave generated by a test unit of the lighting device having the emergency lighting function in accordance with the eleventh embodiment of the disclosure.

FIG. 24 is a second schematic view of the square wave generated by the test unit of the lighting device having the emergency lighting function in accordance with the eleventh embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

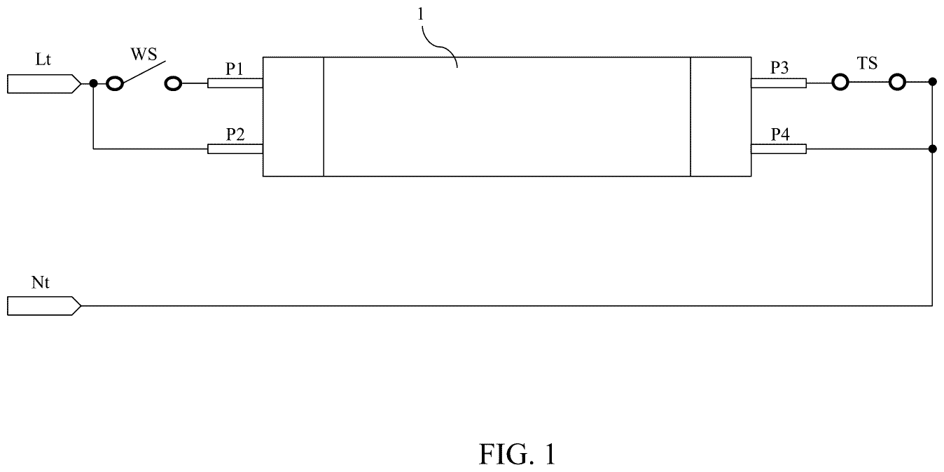

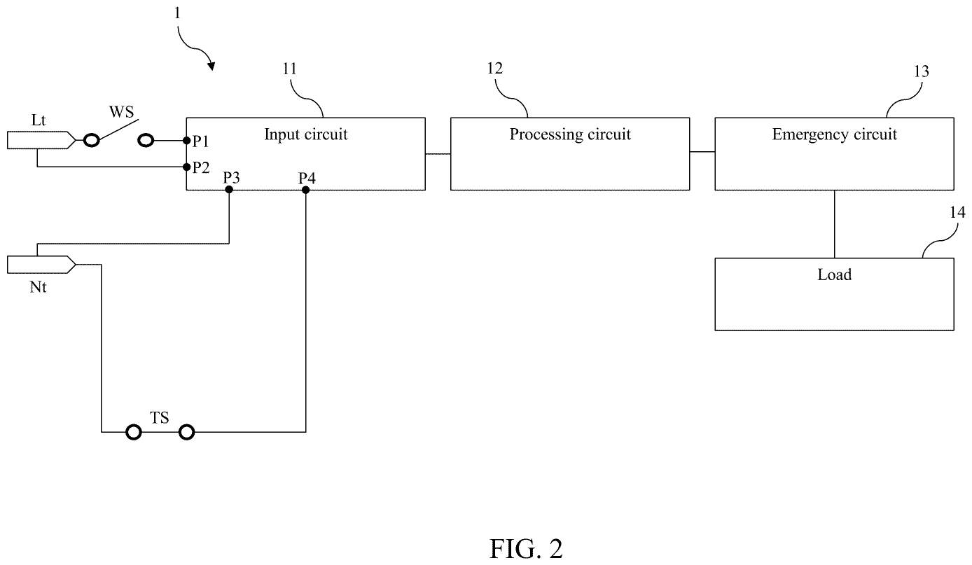

Please refer to FIG. 1 and FIG. 2. FIG. 1 is a schematic view of an emergency lighting device having an emergency test function in accordance with a first embodiment of the disclosure. FIG. 2 is a block diagram of a circuit structure of the emergency lighting device having the emergency test function in accordance with the first embodiment of the disclosure. As shown in FIG. 1 and FIG. 2, the emergency lighting device 1 includes an emergency test switch TS, an input circuit 11, a processing circuit 12, an emergency circuit 13, and a load 14.

The input circuit 11 includes a first pin P1, a second pin P2, a third pin P3, and a fourth pin P4. The first pin P1 is connected to the live-wire output terminal Lt of an external power source through a main switch WS. The second pin P2 is connected to the live-wire output terminal Lt. The third pin P3 is connected to the neutral-wire output terminal Nt of the external power source through the emergency test switch TS. The fourth pin P4 is connected to the neutral-wire output terminal Nt. In one embodiment, the input circuit 11 includes one or more of a rectifying circuit, a filtering circuit, an overcurrent protection circuit, a surge protection circuit, and an electromagnetic interference (EMI) circuit. The circuit structure of the input circuit 11 is well known to those skilled in the art and is therefore not described in further detail. In one embodiment, the main switch WS may be a wall switch, an external control switch, or other currently available switches. In one embodiment, the external power source may be utility power, an AC generator, or other similar devices. In one embodiment, the emergency test switch TS may be an external normally closed switch. In another embodiment, the emergency test switch TS may be a built-in switch.

The processing circuit 12 is connected to the input circuit 11. In one embodiment, the processing circuit 12 may be a microcontroller (MCU), a central-processing unit (CPU), an application-specific integrated circuit (ASIC), a field programmable gate array (FPGA), or other similar components. The circuit structure of the processing circuit 12 is well known to those skilled in the art and is therefore not described in further detail.

The emergency circuit 13 is connected to the processing circuit 12 and includes a rechargeable battery and a charge control circuit. The charge control circuit controls charging and discharging of the rechargeable battery. The circuit structure of the charge control circuit is well known to those skilled in the art and is therefore not described in further detail.

The load 14 is connected to the emergency circuit 13. In one embodiment, the load 14 may be a light source board. In another embodiment, the load 14 may be a light-emitting diode (LED) or a LED array.

When the emergency test switch TS operates in a preset operation mode, the processing circuit 12 receives an emergency test signal and executes an emergency test mode to control the emergency circuit 13 to activate the load 14. The preset operation mode is defined as the emergency test switch TS being maintained in the off state for a preset duration.

For example, the preset duration may be ten seconds. The user may operate the emergency test switch TS to make the emergency test switch TS remain in the off state for ten seconds. At this time, since the emergency test switch TS is turned off, the processing circuit 12 detects that the third pin P3 is not connected to the external power source and that this condition persists for ten seconds. The processing circuit 12 may then execute an emergency test mode. In the emergency test mode, the processing circuit 12 controls the emergency circuit 13 to activate the load 14 to perform the emergency function. The preset duration may be five seconds, seven seconds, or another duration, depending on actual requirements.

Thus, the user can quickly and efficiently perform the emergency test function to verify whether the processing circuit 12 can properly control the emergency circuit 13 to activate the load 14. The user may take necessary measures in a timely manner when an abnormal emergency function is detected.

Through the configuration of the emergency test switch TS, the processing circuit 12 can quickly and effectively execute the emergency test mode to determine whether the emergency function operates normally. Therefore, the reliability of the emergency lighting device 1 can be significantly improved.

In addition, the processing circuit 12 may directly determine whether to initiate the emergency test function in accordance with the electrical level of the third pin P3 (that is, whether the third pin P3 is connected to the external power source). Therefore, regardless of whether the main switch WS is turned on or off, the processing circuit 12 can quickly and effectively execute the emergency test mode. As a result, maintenance of the emergency lighting device 1 is more convenient and meets actual requirements.

The embodiment just exemplifies the disclosure and is not intended to limit the scope of the disclosure; any equivalent modification and variation according to the spirit of the disclosure is to be also included within the scope of the following claims and their equivalents.

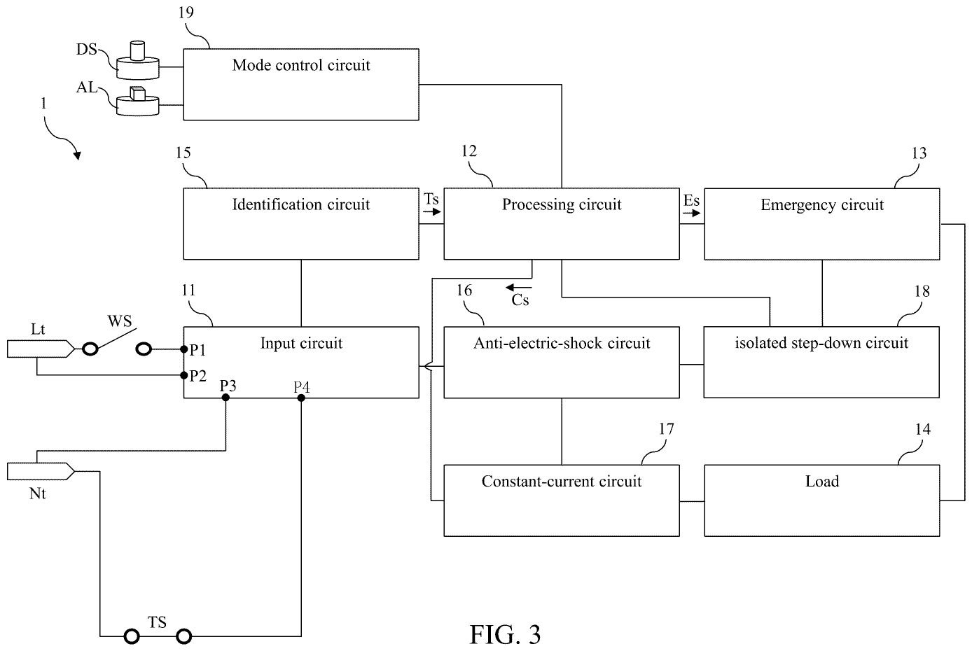

Please refer to FIG. 3, which is a block diagram of a circuit structure of an emergency lighting device having an emergency test function in accordance with a second embodiment of the disclosure. Please also refer to FIG. 1. This embodiment illustrates the complete circuit structure of the emergency lighting device 1. As shown, the emergency lighting device 1 includes an emergency test switch TS, an input circuit 11, an identification circuit 15, a processing circuit 12, an emergency circuit 13, a load 14, an anti-electric-shock circuit 16, a constant-current circuit 17, an isolated step-down circuit 18, a mode control circuit 19, a mode control switch DS, and a warning lamp AL.

The input circuit 11 includes a first pin P1, a second pin P2, a third pin P3, and a fourth pin P4. The first pin P1 is connected to the live-wire output terminal Lt of an external power source through the main switch WS. The second pin P2 is connected to the live-wire output terminal Lt. The third pin P3 is connected to the neutral-wire output terminal Nt of the external power source through the emergency test switch TS. The fourth pin P4 is connected to the neutral-wire output terminal Nt.

The processing circuit 12 is connected to the input circuit 11 through the identification circuit 15 and is further connected to the mode control circuit 19, the emergency circuit 13, and the isolated step-down circuit 18. In addition, the processing circuit 12 is connected to the constant-current circuit 17 through a photo-isolation element (such as an optocoupler). The photo-isolation element provides electrical isolation while allowing the processing circuit 12 to transmit signals to the constant-current circuit 17 to control its operation. In one embodiment, the mode control circuit 19 may be an MCU, a CPU, an ASIC, an FPGA, or other similar components. The circuit structure of the mode control circuit 19 is well known to those skilled in the art and is therefore not described in further detail. In one embodiment, the isolated step-down circuit 18 may be an isolation transformer or other similar components. The circuit structure of the isolated step-down circuit 18 is well known to those skilled in the art and is therefore not described in further detail. In one embodiment, the identification circuit 15 may be a circuit capable of identifying high and low electrical levels. Its structure is well known and will not be repeated here.

The anti-electric-shock circuit 16 is connected to the input circuit 11 and is further connected to the isolated step-down circuit 18 and the constant-current circuit 17. The constant-current circuit 17 is connected to the load 14. In one embodiment, the anti-electric-shock circuit 16 may be a circuit with leakage protection function. In one embodiment, the constant-current circuit 17 may be a buck converter, a boost converter, a buck-boost converter, or other similar components.

When the external power source operates normally and the main switch WS is turned on, the input circuit 11 drives the load 14 to perform a normal lighting mode. When the external power source operates normally and the main switch WS is turned on, the identification circuit 15 determines that the input circuit 11 is connected to the external power source. At this time, the input circuit 11 drives the constant-current circuit 17, which drives the load 14 to perform the normal lighting mode. Meanwhile, the input circuit 11 supplies power to the emergency circuit 13 through the isolated step-down circuit 18, and the processing circuit 12 controls the emergency circuit 13 to enter a charging state.

When the emergency test switch TS operates in the preset operation mode, the processing circuit 12 receives an emergency test signal Ts through the identification circuit 15. At this moment, if the emergency lighting device 1 is operating in the normal lighting mode, the processing circuit 12 transmits an operation signal Cs to the constant-current circuit 17 to turn off the constant-current circuit 17. At the same time, the processing circuit 12 transmits a test control signal Es to the emergency circuit 13 to execute the emergency test mode and control the emergency circuit 13 to activate the load 14.

When the external power source is abnormal, the identification circuit 15 determines that the input circuit 11 is not connected to the external power source. At this time, the processing circuit 12 controls the emergency circuit 13 to drive the load 14 to perform an emergency lighting mode.

The mode control switch DS is connected to the mode control circuit 19. The mode control switch DS is used to control the mode control circuit 19 to generate a mode control signal so as to control the processing circuit 12 to enter a transportation mode. The processing circuit 12 enters a sleep state during the transportation mode and turns off other circuits to reduce power consumption.

In addition, the warning lamp AL is connected to the mode control circuit 19. The mode control circuit 19 may generate a status signal and transmit the status signal to the warning lamp AL so that the warning lamp AL displays the corresponding status in different warning patterns. For example, fault state, charging state, transportation mode, emergency lighting mode, normal lighting mode, and so forth. Therefore, the functions of the emergency lighting device 1 can be more complete in order to satisfy the requirements of various applications.

As described above, the emergency lighting device 1 integrates both normal lighting function and emergency lighting function. The main switch WS is used to control the normal lighting mode. When the external power source (utility power) is abnormal (power failure), the processing circuit 12 executes the emergency lighting mode. When the emergency test switch TS is triggered, the emergency test mode is executed regardless of whether the main switch WS is turned on or off. Accordingly, the user may conveniently perform regular checks on whether the emergency lighting device 1 operates normally and whether maintenance is required.

The embodiment just exemplifies the disclosure and is not intended to limit the scope of the disclosure; any equivalent modification and variation according to the spirit of the disclosure is to be also included within the scope of the following claims and their equivalents.

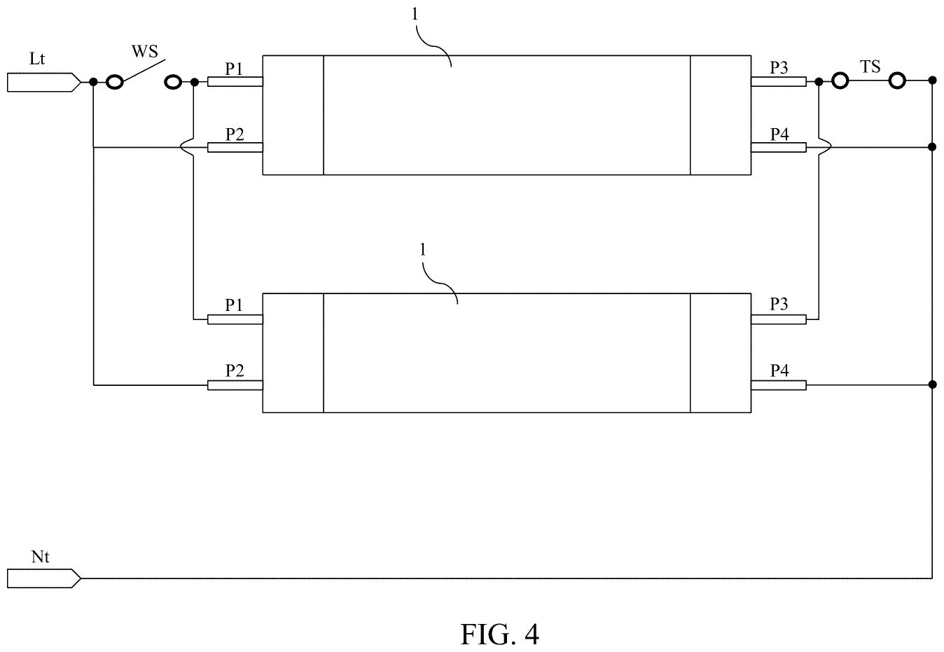

Please refer to FIG. 4, which is a schematic view of an emergency lighting device having an emergency test function in accordance with a third embodiment of the disclosure. Please also refer to FIG. 2. As shown in FIG. 4, the circuit structure of the emergency lighting device 1 is the same as that of the foregoing embodiments, and thus will not be redundantly described here.

The difference between this embodiment and the previous embodiments is that several emergency lighting devices 1 (only two emergency lighting devices 1 are illustrated in FIG. 4) share one emergency test switch TS, and the connection relationship between the emergency test switch TS and the input circuit 11 of each emergency lighting device 1 is the same as that in the first embodiment and the second embodiment, and thus will not be redundantly described here.

The embodiment just exemplifies the disclosure and is not intended to limit the scope of the disclosure; any equivalent modification and variation according to the spirit of the disclosure is to be also included within the scope of the following claims and their equivalents.

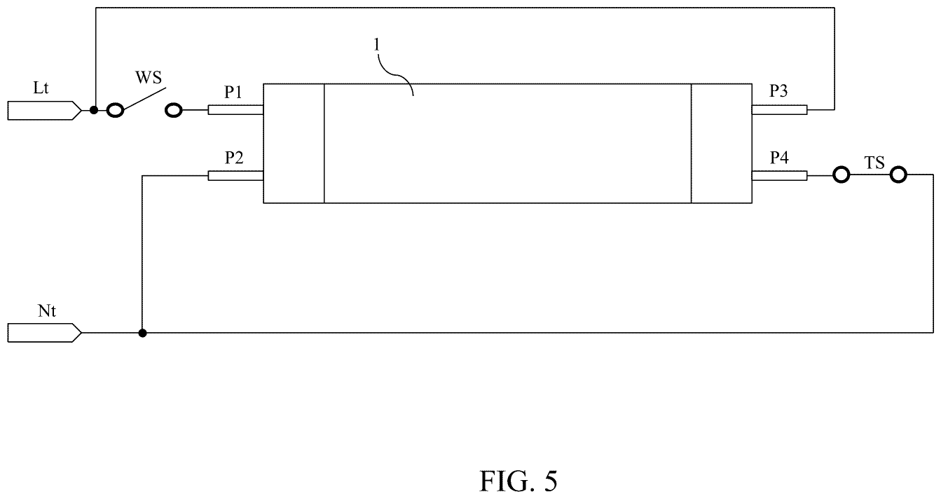

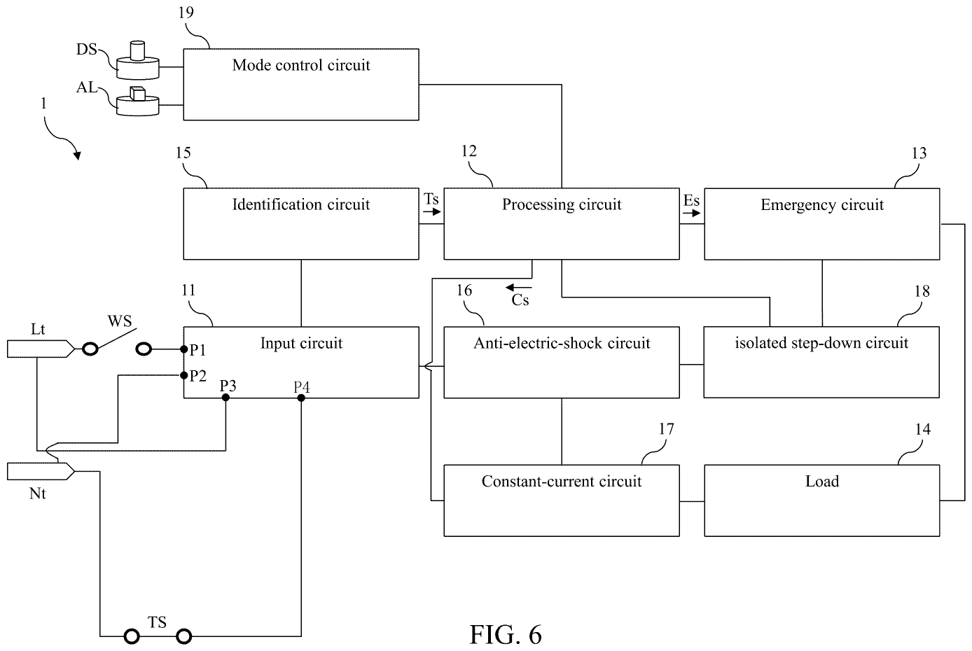

Please refer to FIG. 5 and FIG. 6. FIG. 5 is a schematic view of an emergency lighting device having an emergency test function in accordance with a fourth embodiment of the disclosure. FIG. 6 is a block diagram of a circuit structure of the emergency lighting device having the emergency test function in accordance with the fourth embodiment of the disclosure. As shown in FIG. 5 and FIG. 6, the emergency lighting device 1 includes an emergency test switch TS, an input circuit 11, an identification circuit 15, a processing circuit 12, an emergency circuit 13, a load 14, an anti-electric-shock circuit 16, a constant-current circuit 17, an isolated step-down circuit 18, a mode control circuit 19, a mode control switch DS, and a warning lamp AL. The structures of the above elements are the same as those in the second embodiment, and thus will not be redundantly described here.

The difference between this embodiment and the previous embodiments is that the connection relationship of the input circuit 11 of the emergency lighting device 1. The first pin P1 is connected to the live-wire output terminal Lt of an external power source through a main switch WS. The second pin P2 is connected to the neutral-wire output terminal Nt of the external power source. The third pin P3 is connected to the live-wire output terminal Lt. The fourth pin P4 is connected to the neutral-wire output terminal Nt through the emergency test switch TS.

Likewise, when the emergency test switch TS is operated in the preset operation mode, the processing circuit 12 receives an emergency test signal Ts from the identification circuit 15. At this time, when the emergency lighting device 1 is in the normal lighting mode, the processing circuit 12 transmits a control signal Cs to the constant-current circuit 17 to turn off the constant-current circuit 17. Meanwhile, the processing circuit 12 transmits a test control signal Es to the emergency circuit 13 to execute the emergency test mode and control the emergency circuit 13 to activate the load 14.

Through the design of the emergency test switch TS, the processing circuit 12 can quickly and effectively execute the emergency test mode to test whether the emergency function operates normally. Therefore, the reliability of the emergency lighting device 1 can be greatly improved.

In addition, the processing circuit 12 may directly determine whether to activate the emergency test function based on the level state of the fourth pin P4 (whether the fourth pin P4 is connected to the external power source). Therefore, regardless of whether the main switch WS is in the on state or the off state, the processing circuit 12 can quickly and effectively execute the emergency test mode. Accordingly, the maintenance of the emergency lighting device 1 can be more convenient to meet actual application requirements.

The embodiment just exemplifies the disclosure and is not intended to limit the scope of the disclosure; any equivalent modification and variation according to the spirit of the disclosure is to be also included within the scope of the following claims and their equivalents.

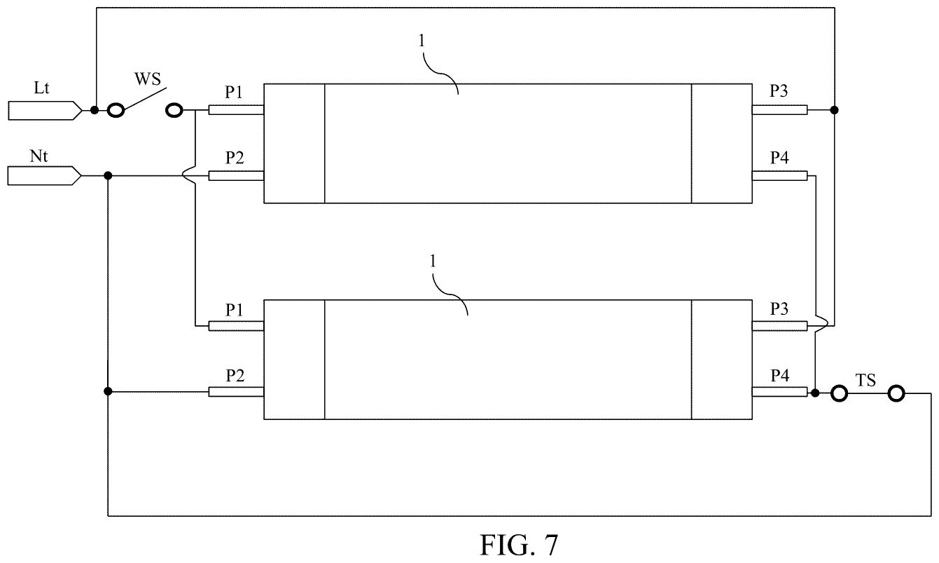

Please refer to FIG. 7, which is a schematic view of an emergency lighting device having an emergency test function in accordance with a fifth embodiment of the disclosure. Please also refer to FIG. 6. As shown in FIG. 7, the circuit structure of the emergency lighting device 1 is the same as that of the foregoing embodiments, and thus will not be redundantly described here.

The difference between this embodiment and the previous embodiments is that several emergency lighting devices 1 (only two emergency lighting devices 1 are illustrated in FIG. 7) share one emergency test switch TS, and the connection relationship between the emergency test switch TS and the input circuit 11 of each emergency lighting device 1 is the same as that in the third embodiment, and thus will not be redundantly described here.

The embodiment just exemplifies the disclosure and is not intended to limit the scope of the disclosure; any equivalent modification and variation according to the spirit of the disclosure is to be also included within the scope of the following claims and their equivalents.

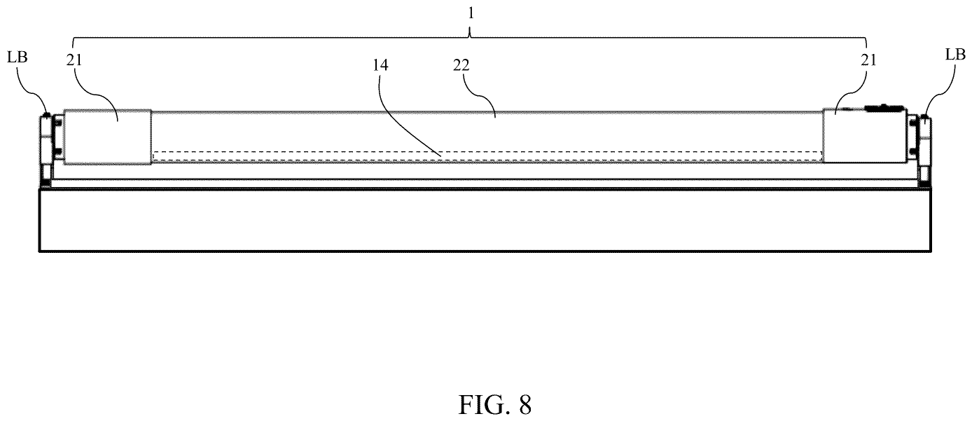

Please refer to FIG. 8, which is a side view of an emergency lighting device having an emergency test function in accordance with a sixth embodiment of the disclosure. Please also refer to FIG. 5 and FIG. 6. As shown in FIG. 8, the emergency lighting device 1 further includes two end caps 21 and a tube body 22, and the two end caps 21 are respectively disposed at the two ends of the tube body 22. The input circuit 11, the identification circuit 15, the processing circuit 12, the emergency circuit 13, the load 14, the anti-electric-shock circuit 16, the constant-current circuit 17, the isolated step-down circuit 18, and the mode control circuit 19 may be disposed in the tube body 22 or in one of the end caps 21. The emergency lighting device 1 may be installed on a lamp base LB to be connected with an external power source (such as utility power). As previously described, the emergency test switch TS may be an external normally closed switch and may be disposed on one of the end caps 21.

The size of the end cap 21 is reduced so that the tube body 22 of the emergency lighting device 1 can be extended. Therefore, the light efficiency of the emergency lighting device 1 can be significantly enhanced.

The embodiment just exemplifies the disclosure and is not intended to limit the scope of the disclosure; any equivalent modification and variation according to the spirit of the disclosure is to be also included within the scope of the following claims and their equivalents.

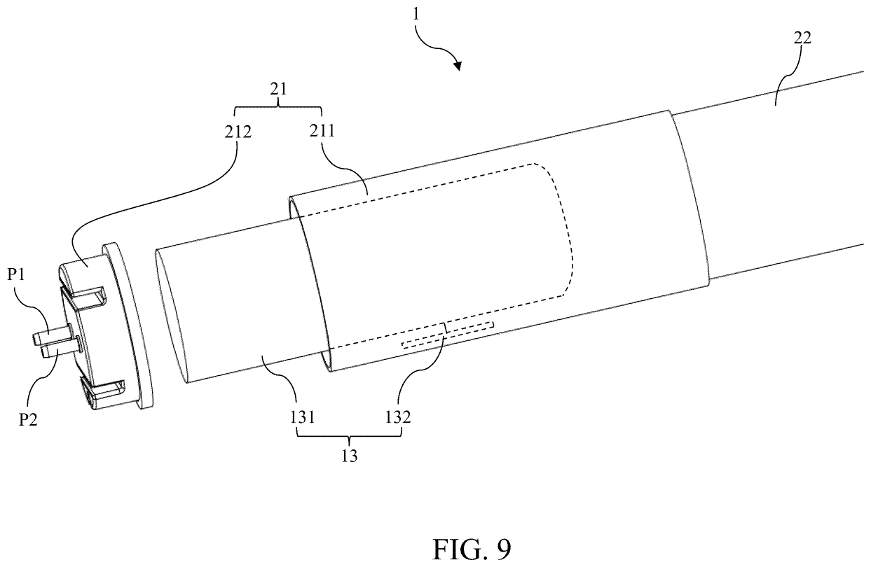

Please refer to FIG. 9, which is a first partial enlargement view of the emergency lighting device having the emergency test function in accordance with the sixth embodiment of the disclosure. Please also refer to FIG. 5 and FIG. 6. As shown in FIG. 9, each end cap 21 includes a tubular body 211 and a cover 212. The cover 212 is detachably disposed on the tubular body 211.

The first pin P1 and the second pin P2 of the input circuit 11 are disposed on one of the end caps 21. As previously described, the emergency circuit 13 includes a rechargeable battery 131 and a charge control circuit 132. The rechargeable battery 131 is detachably disposed in the tubular body 211.

Thus, when the rechargeable battery 131 fails, the user may directly remove the cover 212 of the end cap 21 and replace the rechargeable battery 131 to allow the emergency lighting device to operate normally.

The embodiment just exemplifies the disclosure and is not intended to limit the scope of the disclosure; any equivalent modification and variation according to the spirit of the disclosure is to be also included within the scope of the following claims and their equivalents.

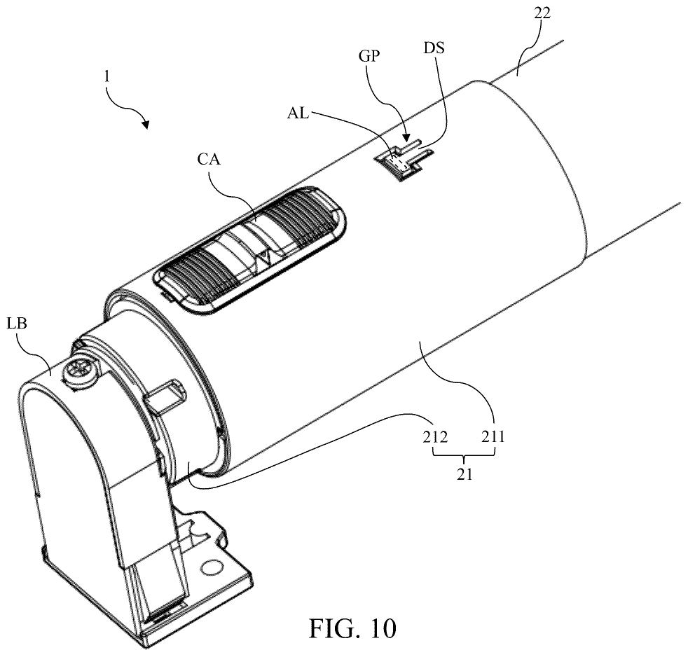

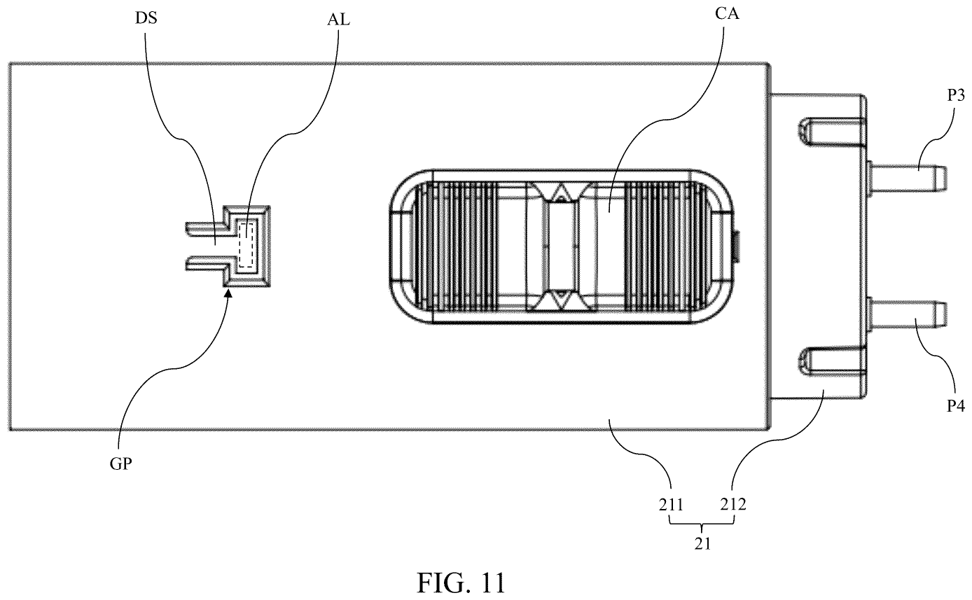

Please refer to FIG. 10 and FIG. 11. FIG. 10 is a second partial enlargement view of the emergency lighting device having the emergency test function in accordance with the sixth embodiment of the disclosure. FIG. 11 is a third partial enlargement view of the emergency lighting device having the emergency test function in accordance with the sixth embodiment of the disclosure. Please also refer to FIG. 5 and FIG. 6. As shown in FIG. 10 and FIG. 11, the third pin P3 and the fourth pin P4 of the input circuit 11 are disposed on another end cap 21. The mode control switch DS and the warning lamp AL may be disposed on this end cap 21, and the end cap 21 may further include a color temperature adjustment switch CA, which is connected to the processing circuit 12.

A light-transmissive groove GP is formed around the mode control switch DS, and the warning lamp AL is disposed below the mode control switch DS. In this embodiment, the mode control switch DS is T-shaped, and the light-transmissive groove GP surrounds the mode control switch DS. This integrated design enables the light emitted by the warning lamp AL to directly pass through the light-transmissive groove GP, thereby increasing the light-emitting area of the warning lamp AL. Accordingly, the user can quickly identify the status of the emergency lighting device 1 based on the light emitted by the warning lamp AL.

In addition, the user may adjust the color temperature of the emergency lighting device 1 by operating the color temperature adjustment switch CA to achieve a desired lighting effect. Therefore, the emergency lighting device 1 can provide a wider range of color temperatures, such that the emergency lighting device 1 can be more comprehensive in application and more flexible in use.

The embodiment just exemplifies the disclosure and is not intended to limit the scope of the disclosure; any equivalent modification and variation according to the spirit of the disclosure is to be also included within the scope of the following claims and their equivalents.

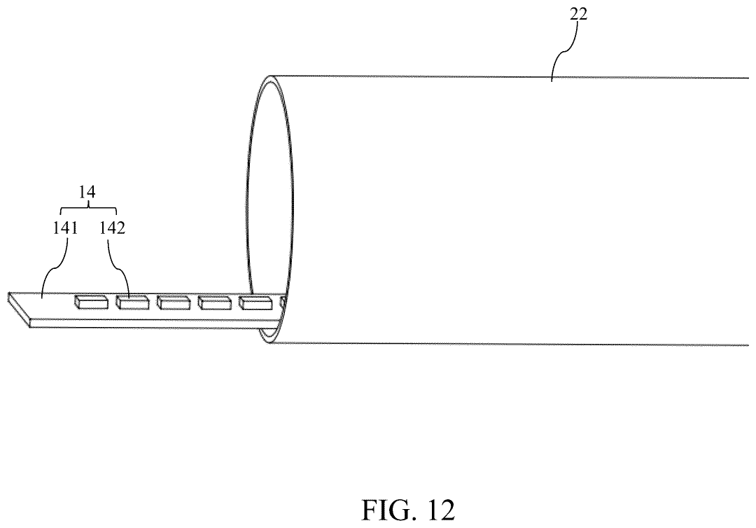

Please refer to FIG. 12, which is a fourth partial enlargement view of the emergency lighting device having the emergency test function in accordance with the sixth embodiment of the disclosure. Please also refer to FIGS. 5 and 6. As shown in FIG. 12, the load 14 may be disposed in the tube body 22. The load 14 may be a light source board that includes a circuit board 141 and a plurality of light sources 142 (only a portion of the light sources 142 are illustrated, and the number of light sources 142 may be adjusted based on actual needs). The light sources 142 may be LEDs. In this embodiment, the circuit board 141 may be a flexure circuit board, and the tube body 22 may be a glass tube. The combination of a flexure circuit board and a glass tube can significantly reduce the difficulty of the manufacturing process of the emergency lighting device 1, thereby reducing labor costs. Therefore, the manufacturing cost of the emergency lighting device 1 can be lowered.

In another embodiment, the circuit board 141 may be a printed circuit board or a rigid-flex board, and the tube body 22 may be made of other transparent or semi-translucent materials such as plastic.

The embodiment just exemplifies the disclosure and is not intended to limit the scope of the disclosure; any equivalent modification and variation according to the spirit of the disclosure is to be also included within the scope of the following claims and their equivalents.

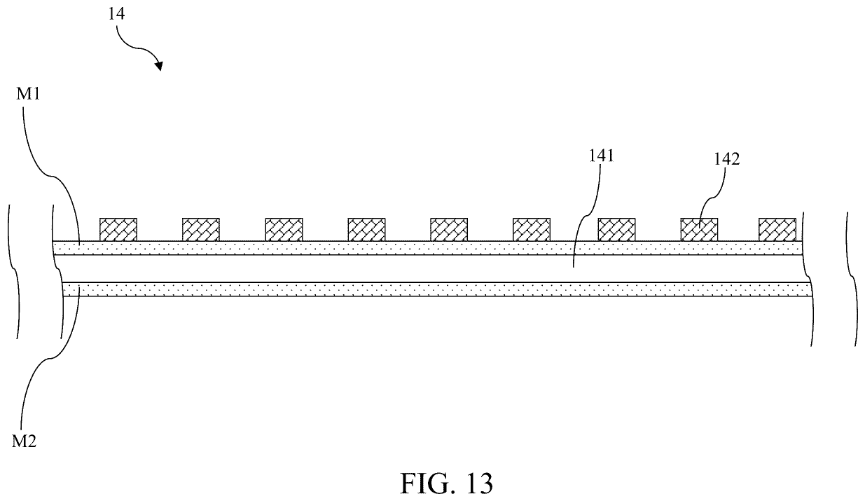

Please refer to FIG. 13, which is a schematic view of a load of the emergency lighting device having the emergency test function in accordance with the sixth embodiment of the disclosure. As shown in FIG. 13, the load 14 (light source board) may include the circuit board 141 and a plurality of light sources 142. The circuit board 141 may be a flexible circuit board. An upper metal layer M1 is disposed on the upper surface of the circuit board 141, and a lower metal layer M2 is disposed on the lower surface of the circuit board 141. The light sources 142 are disposed on the upper metal layer M1. The upper metal layer M1 and the lower metal layer M2 may be copper or other metal materials (such as gold or silver).

The upper metal layer M1 and the lower metal layer M2 may be formed on the upper and lower surfaces of the circuit board 141 through electroplating or similar processes.

The upper metal layer M1 and the lower metal layer M2 provide heat dissipation function. Therefore, the circuit board 141 having metal plating on both surfaces can achieve improved heat dissipation performance, thereby extending the service life of the load 14. Moreover, the upper metal layer M1 and the lower metal layer M2 may also increase the hardness of the circuit board 141, enabling the circuit board 141 with double-sided metal plating to achieve greater structural strength. Thus, the circuit board 141 can be stably disposed in the tube body 22 without easily bending.

The embodiment just exemplifies the disclosure and is not intended to limit the scope of the disclosure; any equivalent modification and variation according to the spirit of the disclosure is to be also included within the scope of the following claims and their equivalents.

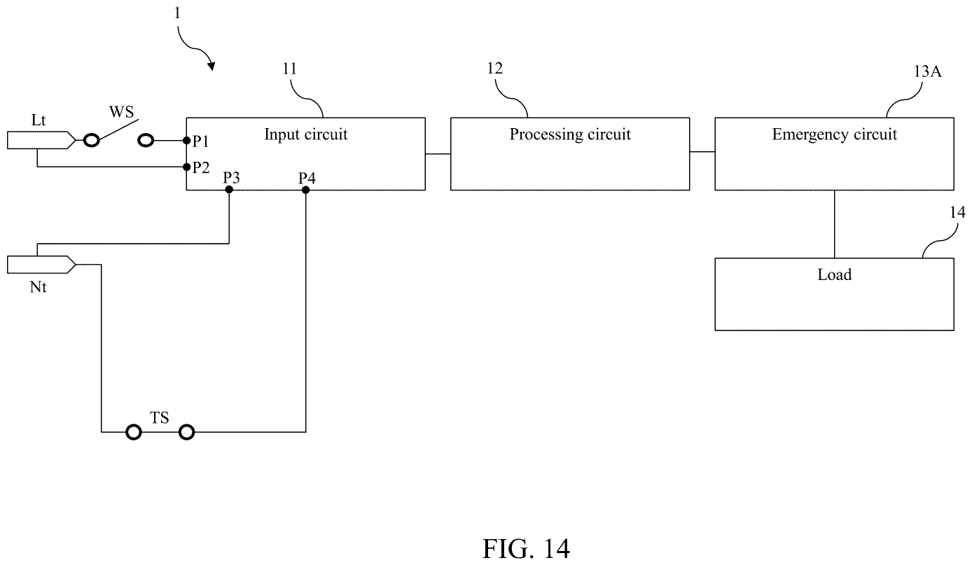

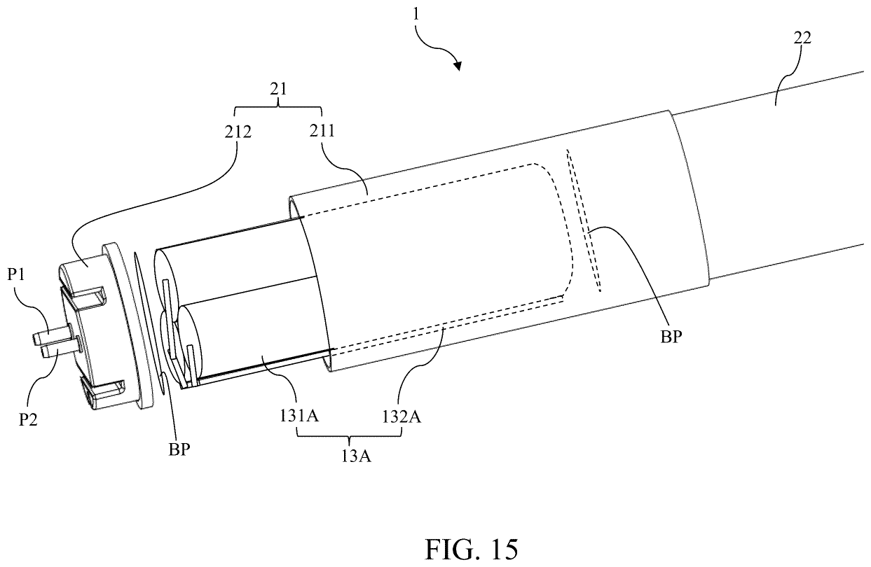

Please refer to FIGS. 14 and 15. FIG. 14 is a block diagram of a circuit structure of an emergency lighting device having an emergency test function in accordance with a seventh embodiment of the disclosure. FIG. 15 is a partial enlargement view of the emergency lighting device having the emergency test function in accordance with the seventh embodiment of the disclosure. As shown in FIGS. 14 and 15, the emergency lighting device 1 includes an emergency test switch TS, an input circuit 11, a processing circuit 12, an emergency circuit 13, and a load 14.

The emergency lighting device 1 includes the emergency test switch TS, the input circuit 11, the processing circuit 12, the emergency circuit 13, and the load 14.

The input circuit 11 includes a first pin P1, a second pin P2, a third pin P3, and a fourth pin P4. The first pin P1 is connected to the live-wire output terminal Lt of an external power source through a main switch WS. The second pin P2 is connected to the live-wire output terminal Lt. The third pin P3 is connected to the neutral-wire output terminal Nt of the external power source through the emergency test switch TS. The fourth pin P4 is connected to the neutral-wire output terminal Nt. The processing circuit 12 is connected to the input circuit 11. The load 14 is connected to the emergency circuit 13A. The emergency circuit 13A is connected to the processing circuit 12.

The emergency lighting device 1 further includes two end caps 21 (only one end cap 21 is shown in FIG. 15) and a tube body 22. The two end caps 21 are respectively disposed at the two ends of the tube body 22. Each end cap 21 includes a tubular body 211 and a cover 212. The cover 212 is detachably disposed on the tubular body 211. The input circuit 11, the identification circuit 15, the processing circuit 12, the emergency circuit 13, and the load 14 may all be disposed in the tube body 22 or in one of the end caps 21. The first pin P1 and the second pin P2 of the input circuit 11 are disposed on one of the end caps 21.

The emergency circuit 13A includes a rechargeable battery 131A and a charge control circuit 132A.

The difference between this embodiment and the first embodiment is that the rechargeable battery 131A of this embodiment includes three battery elements BT. Each battery element BT may be cylindrical. The three battery elements BT are arranged in a pyramidal shape. The battery elements BT may be lithium-ion batteries, lithium polymer batteries, nickel-metal hydride batteries, or other similar components.

In another embodiment, the battery elements BT may also have a polygonal column structure (such as a pentagonal or hexagonal column), and may be modified according to actual requirements.

The emergency lighting device 1 further includes two buffer pads BP, respectively disposed at the two ends of the rechargeable battery 131A. In one embodiment, each buffer pad BP may be made of silicone, rubber, or other elastic materials. The buffer pads BP can effectively absorb vibration energy to prevent the rechargeable battery 131A from being damaged by vibration or other external forces.

The embodiment just exemplifies the disclosure and is not intended to limit the scope of the disclosure; any equivalent modification and variation according to the spirit of the disclosure is to be also included within the scope of the following claims and their equivalents.

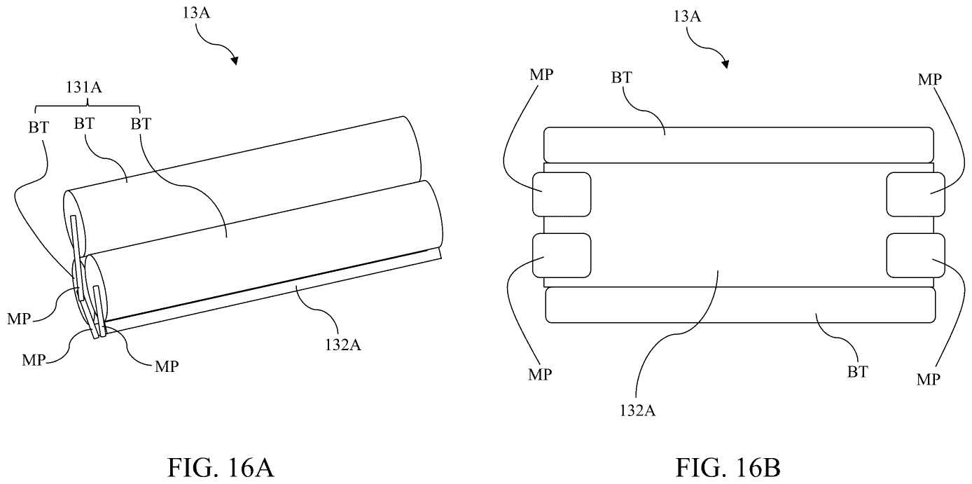

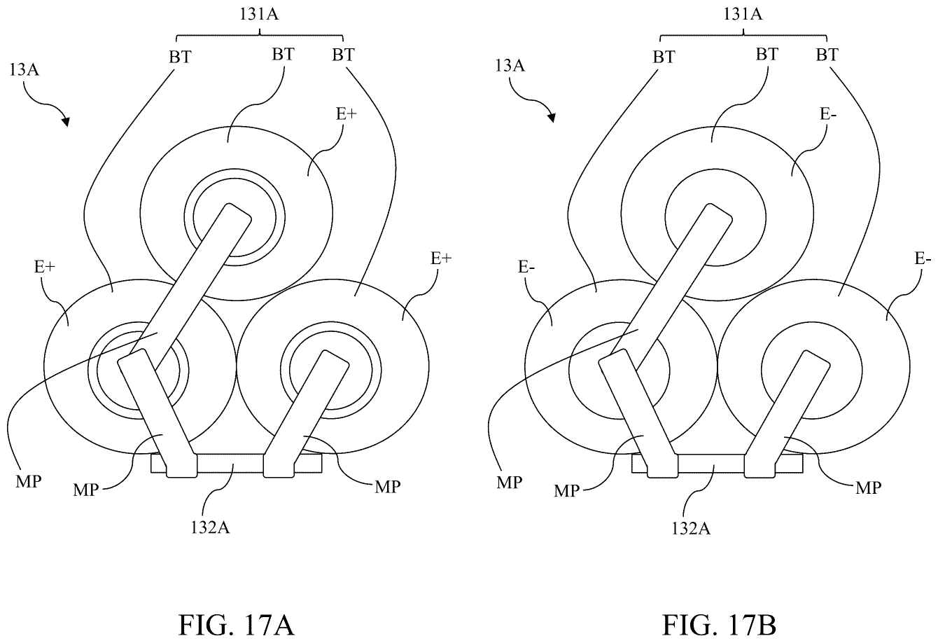

Please refer to FIG. 16A, FIG. 16B, FIG. 17A, and FIG. 17B. FIG. 16A is a perspective view of an emergency circuit of the emergency lighting device having the emergency test function in accordance with the seventh embodiment of the disclosure. FIG. 16B is a bottom view of the emergency circuit of the emergency lighting device having the emergency test function in accordance with the seventh embodiment of the disclosure. FIG. 17A is a first side view of an emergency circuit of the emergency lighting device having the emergency test function in accordance with the seventh embodiment of the disclosure. FIG. 17B is a second side view of the emergency circuit of the emergency lighting device having the emergency test function in accordance with the seventh embodiment of the disclosure. As shown in FIG. 16A, FIG. 16B, FIG. 17A, and FIG. 17B, the three battery elements BT are arranged in a pyramidal shape, forming a structure similar to a triangular prism. The charge control circuit 132A is disposed between two of the battery elements BT and covers the gap between the two battery elements BT. In this manner, the emergency circuit 13A (including the rechargeable battery 131A and the charge control circuit 132A) can be detachably disposed inside the tubular body 211.

The above three-dimensional pyramidal arrangement optimizes the space utilization of the end cap 21, allowing the internal space of the end cap 21 to accommodate the maximum number of battery elements BT. Therefore, it is particularly suitable for use in the emergency lighting device 1.

In addition, the charge control circuit 132A can independently manage each battery element BT. Thus, the charge control circuit 132A can individually monitor the voltage, current, and temperature of each battery element BT and perform protection functions.

Furthermore, the connection wires between the charge control circuit 132A and each battery element BT are extremely short, allowing rapid and real-time response to abnormal conditions to prevent thermal runaway of the battery elements BT. As a result, the safety of the emergency lighting device 1 can be significantly enhanced.

The battery elements BT may be electrically connected to the charge control circuit 132A through a plurality of metal conductive sheets MP. For example, the positive electrode E+ of the topmost battery element BT may be connected to the positive electrode E+ of the left battery element BT through a metal conductive sheet MP (such as an aluminum sheet, copper sheet, or alloy sheet). The two ends of the metal conductive sheet MP may be soldered respectively to the positive electrodes E+ of the two battery elements BT. The positive electrode E+ of the left battery element BT may be connected to the charge control circuit 132A through another metal conductive sheet MP. The two ends of the metal conductive sheet MP may be soldered respectively to the positive electrode E+ of the battery element BT and the positive terminal of the charge control circuit 132A. The positive electrode E+ of the right battery element BT may also be connected to the charge control circuit 132A through a metal conductive sheet MP. The two ends of the metal conductive sheet MP may be soldered respectively to the positive electrode E+ of the battery element BT and the positive terminal of the charge control circuit 132A. Similarly, the negative electrodes E− of the battery elements BT may be connected to the charge control circuit 132A in the same manner.

The structural design integrating the metal conductive sheets MP not only achieves electrical connection between the battery elements BT and the charge control circuit 132A but also enhances the structural stability of the rechargeable battery 131A, preventing the battery elements BT from loosening or separating.

The embodiment just exemplifies the disclosure and is not intended to limit the scope of the disclosure; any equivalent modification and variation according to the spirit of the disclosure is to be also included within the scope of the following claims and their equivalents.

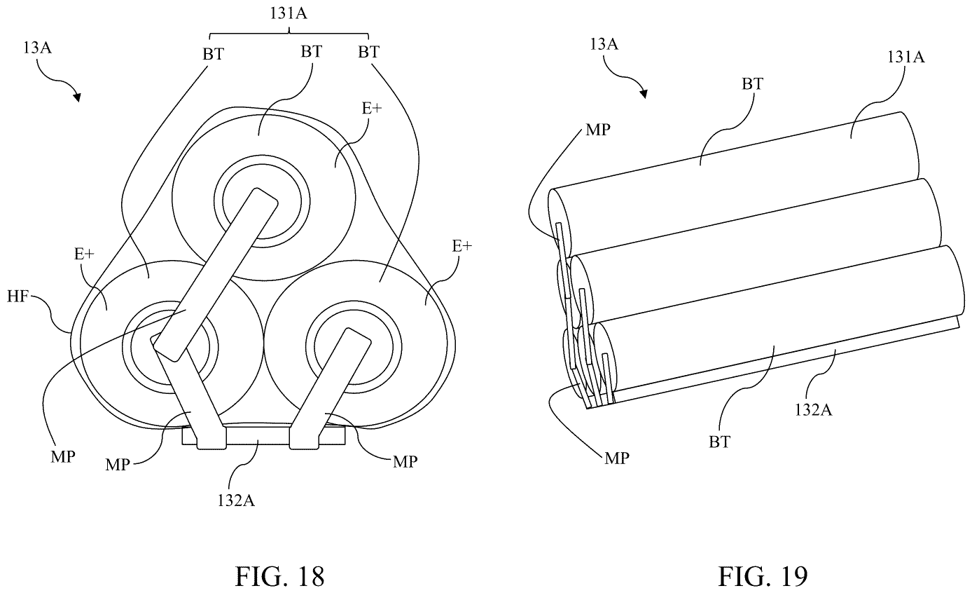

Please refer to FIG. 18, which is a third side view of the emergency circuit of the emergency lighting device having the emergency test function in accordance with the seventh embodiment of the disclosure. As shown in FIG. 18, the rechargeable battery 131A may further include a heat-shrink film HF, which covers the rechargeable battery 131A to further enhance its structural stability.

The embodiment just exemplifies the disclosure and is not intended to limit the scope of the disclosure; any equivalent modification and variation according to the spirit of the disclosure is to be also included within the scope of the following claims and their equivalents.

Please refer to FIG. 19, which is a perspective view of an emergency circuit of an emergency lighting device having an emergency test function in accordance with an eighth embodiment of the disclosure. As shown in FIG. 19, the number of battery elements BT of the rechargeable battery 131A may be modified according to actual needs. For example, in this embodiment, the rechargeable battery 131A includes six battery elements BT.

Similarly, the six battery elements BT are arranged in a pyramidal shape, forming a structure similar to a triangular prism. The charge control circuit 132A is disposed between three of the battery elements BT and covers the gaps between the three battery elements BT.

Currently available emergency lighting devices lack an effective emergency test function. The emergency test function serves as a key method to verify whether the emergency lighting device can activate properly when needed. Yet, current emergency lighting devices are unable to quickly and effectively check whether their emergency functions can operate correctly. By contrast, according to one embodiment of the disclosure, the emergency lighting device includes an emergency test switch, an input circuit, a processing circuit, an emergency circuit, and a load. The input circuit has a first pin, a second pin, a third pin, and a fourth pin. The first pin is connected to the live-wire output terminal of an external power source via a main switch. The second pin is connected to the live-wire output terminal. The third pin is connected to the neutral-wire output terminal of the external power source via the emergency test switch. The fourth pin is connected to the neutral-wire output terminal. The processing circuit is connected to the input circuit. The emergency circuit is connected to the processing circuit. The load is connected to the emergency circuit. The processing circuit receives an emergency test signal when the emergency test switch is operated in a preset operation mode and executes an emergency test mode to control the emergency circuit to activate the load. Through the design of the emergency test switch, the processing circuit can quickly and effectively execute the emergency test mode to test whether the emergency function is normal. Therefore, the reliability of the emergency lighting device can be significantly enhanced.

According to one embodiment of the disclosure, the processing circuit receives the emergency test signal when the emergency test switch is operated in the preset operation mode and executes the emergency test mode to control the emergency circuit to activate the load. The preset operation mode is that the emergency test switch remains in the off state for a preset duration. Through the circuit design of the emergency lighting device and the activation mechanism of the emergency test mode, the processing circuit can directly determine whether to start the emergency test function according to the electrical level of the third pin (that is, whether the third pin is connected to the external power source). Therefore, whether the main switch is in the on state or the off state, the processing circuit can quickly and effectively execute the emergency test mode. As a result, maintenance of the emergency lighting device can be more convenient to meet actual requirements.

Also, according to one embodiment of the disclosure, the emergency lighting device further includes a mode control switch and a mode control circuit. The mode control circuit is connected to the processing circuit. The mode control switch is connected to the mode control circuit. The mode control switch controls the mode control circuit to generate a mode control signal to control the processing circuit to enter a transportation mode. In the transportation mode, the processing circuit enters a sleep state. Through the mode control switch and the mode control circuit, the processing circuit can execute the transportation mode to reduce power consumption during transportation. Therefore, the emergency lighting device can provide additional functions, such that the emergency lighting device can be more convenient in use and comprehensive in application.

Further, according to one embodiment of the disclosure, the emergency lighting device further includes a warning lamp connected to the mode control circuit. The mode control circuit can generate a status signal and transmit it to the warning lamp, allowing the warning lamp to display the corresponding status according to different warning patterns. For example, the status may indicate fault state, charging state, transportation mode, emergency lighting mode, or normal lighting mode. Therefore, the functions of the emergency lighting device can be more complete to meet the requirements of different applications.

Moreover, according to one embodiment of the disclosure, the rechargeable battery of the emergency circuit of the emergency lighting device includes a plurality of battery elements. These battery elements can be arranged in a pyramidal shape to form a structure similar to a triangular prism. The emergency circuit can be disposed in the end cap of the emergency lighting device. The above three-dimensional pyramidal structure optimizes the space utilization of the end cap, allowing the internal space of the end cap to accommodate the maximum number of battery elements.

Furthermore, according to one embodiment of the disclosure, the design of the emergency lighting device is simple, and the desired functions can be achieved without significantly increasing cost. Therefore, the practicality of the emergency lighting device can be greatly enhanced and can meet future development trends.

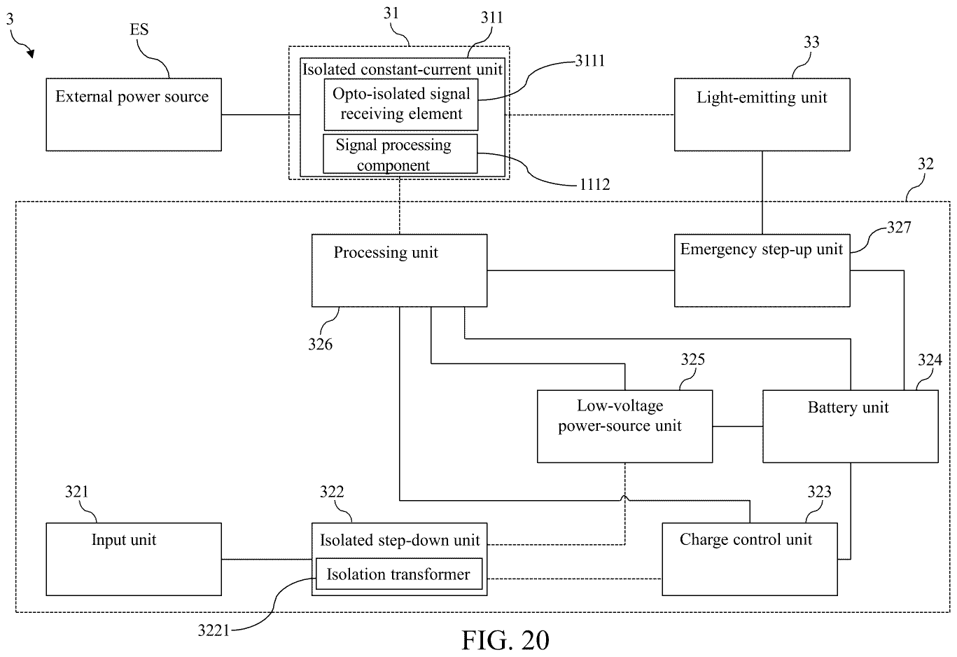

The disclosure further discloses a lighting device having an emergency lighting function. Please refer to FIG. 20, which is a block diagram of a circuit structure of a lighting device having an emergency lighting function in accordance with a ninth embodiment of the disclosure. As shown in FIG. 20, the lighting device 3 includes a light emitting module 33, a main lighting power-supply module 31, and an emergency lighting power-supply module 32.

The light emitting module 33 may include one or more LEDs. In another embodiment, the light emitting module 33 may also be a light bulb, a light tube, other similar light sources.

The main lighting power-supply module 31 includes an isolated constant-current unit 311. The main lighting power-supply module 31 is connected to the light emitting module 33 and an external power source ES. The isolated constant-current unit 311 includes an opto-isolated signal receiving element 3111, a signal processing element 3112 (such as an optocoupler or other similar components), and a constant-current circuit. The circuit structure thereof is known to those skilled in the art and will not be further detailed herein. In one embodiment, the external power source ES may be a wall switch or another similar switch connected to a power supply network (utility power).

The emergency lighting power-supply module 32 includes an input unit 321, an emergency step-up unit 327, a battery unit 324, a charge control unit 323, an isolated step-down unit 322, a processing unit 326, and a low-voltage power-source unit 325.

The emergency step-up unit 327 is connected to the light emitting module 33. The emergency step-up unit 327 may include a boost conversion circuit, the circuit structure thereof is known to those skilled in the art and therefore will not be further described.

The battery unit 324 is connected to the emergency step-up unit 327. The battery unit 324 may be a rechargeable battery such as a lithium-ion battery, a lithium polymer battery, a nickel-metal hydride battery, or other similar components.

The charge control unit 323 is connected to the battery unit 324. The charge control unit 323 may include a controller and a battery level monitoring circuit. The battery level monitoring circuit may detect the charge level of the battery unit 324. Its circuit structure is known to those skilled in the art and will not be further detailed. The controller may be a MCU, a CPU, an ASIC, a FPGA, or other similar components.

The isolated step-down unit 322 is connected to the charge control unit 323. The isolated step-down unit 322 includes an isolation transformer 3221, the circuit structure thereof is known to those skilled in the art and will not be further described.

The input unit 321 is connected to the isolated step-down unit 322. The input unit 321 may include a live-wire input terminal and a neutral-wire input terminal and may be connected to the power supply network (utility power).

The low-voltage power-source unit 325 is connected to the processing unit 326, the isolated step-down unit 322, and the battery unit 324. The low-voltage power-source unit 325 includes a conversion circuit, the circuit structure thereof is known to those skilled in the art and will not be further detailed.

As described above, the isolated step-down unit 322 includes the isolation transformer 3221. The charge control unit 323 and the low-voltage power-source unit 325 communicate with the isolated step-down unit 322.

The processing unit 326 is connected to the emergency step-up unit 327, the battery unit 324, the low-voltage power-source unit 325, and the charge control unit 323. As described above, the isolated constant-current unit 311 includes the opto-isolated signal receiving element 3111 and the signal processing element 3112, and the processing unit 326 communicates with the isolated constant-current unit 311 (the main lighting power-supply module 31). The processing unit 326 may be a MCU, a CPU, an ASIC, an FPGA, or other similar components.

Through the isolated circuit design described above, the main lighting power-supply module 31 and the emergency lighting power-supply module 32 can be electrically isolated from each other to achieve a good isolation effect (the dotted line in FIG. 20 indicates the isolation effect). Therefore, the safety of the lighting device 3 is significantly enhanced to meet actual requirements.

When the power supply network operates normally, the lighting device 3 operates in the normal working mode. At this time, the power supply network drives the main lighting power-supply module 31 (the isolated constant-current unit 311) to supply power to the light emitting module 33. Meanwhile, the power supply network supplies power through the input unit 321 and the isolated step-down unit 322 to the charge control unit 323, the battery unit 324, the low-voltage power-source unit 325, the processing unit 326, and the emergency step-up unit 327. The processing unit 326 performs a charging mode to activate the charge control unit 323 to charge the battery unit 324 and to control the charge control unit 323 to perform various power management functions.

When the power supply network is abnormal (power failure), the battery unit 324 drives the low-voltage power-source unit 325 to supply power to the processing unit 326. The battery unit 324 drives the emergency step-up unit 327 to supply power to the light emitting module 33. The processing unit 326 appropriately controls the emergency step-up unit 327 so that the light emitting module 33 can operate normally.

The embodiment just exemplifies the disclosure and is not intended to limit the scope of the disclosure; any equivalent modification and variation according to the spirit of the disclosure is to be also included within the scope of the following claims and their equivalents.

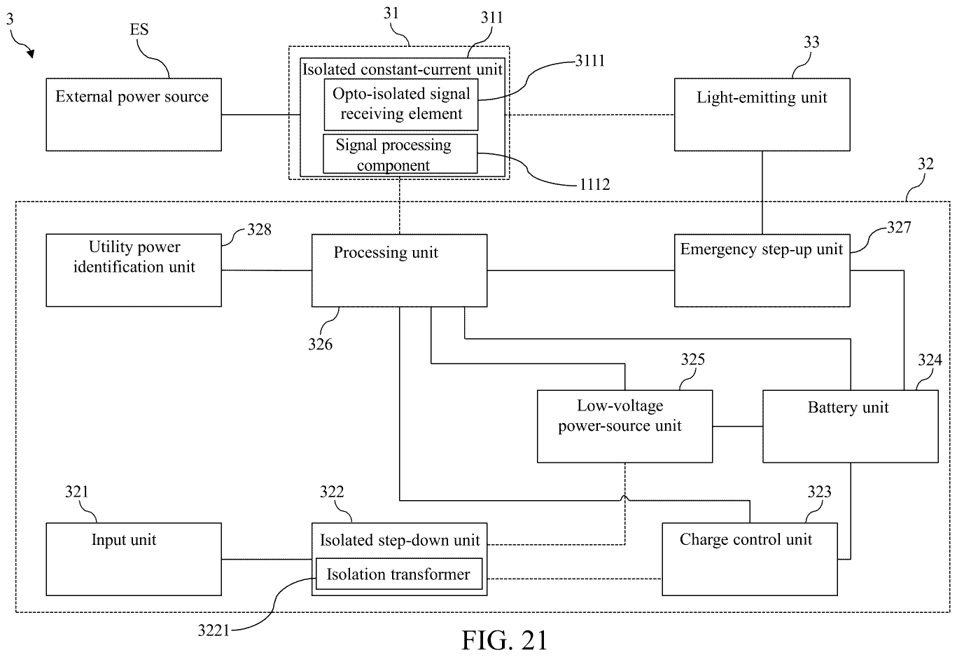

Please refer to FIG. 21, which is a block diagram of a circuit structure of a lighting device having an emergency lighting function in accordance with a tenth embodiment of the disclosure. As shown in FIG. 21, the lighting device 3 includes a light emitting module 33, a main lighting power-supply module 31, and an emergency lighting power-supply module 32.

The light emitting module 33 may include one or more LEDs. The main lighting power-supply module 31 includes an isolated constant-current unit 311. The emergency lighting power-supply module 32 includes an input unit 321, an emergency step-up unit 327, a battery unit 324, a charge control unit 323, an isolated step-down unit 322, a processing unit 326, and a low-voltage power-source unit 325.

The above elements are similar to those in the previous embodiment and will not be further detailed. The difference between this embodiment and the previous embodiment is that the emergency lighting power-supply module 32 of this embodiment further includes a utility power identification unit 328.

The utility power identification unit 328 is connected to the processing unit 326, which can generate an identification signal. The utility power identification unit 328 may include a voltage detection circuit or a current detection circuit. The circuit structure thereof is known to those skilled in the art and will not be further described.

When the power supply network is abnormal (power failure), the utility power identification unit 328 generates the identification signal indicating the abnormal state. At this time, the processing unit 326 performs an emergency mode according to the identification signal. In the emergency mode, the processing unit 326 activates the emergency step-up unit 327 to drive the light emitting module 33 to perform an emergency lighting function.

When the power supply network operates normally, the utility power identification unit 328 generates the identification signal indicating the normal state. At this time, the processing unit 326 performs the charging mode according to the identification signal. In the charging mode, the processing unit 326 activates the charge control unit 323 to charge the battery unit 324.

The embodiment just exemplifies the disclosure and is not intended to limit the scope of the disclosure; any equivalent modification and variation according to the spirit of the disclosure is to be also included within the scope of the following claims and their equivalents.

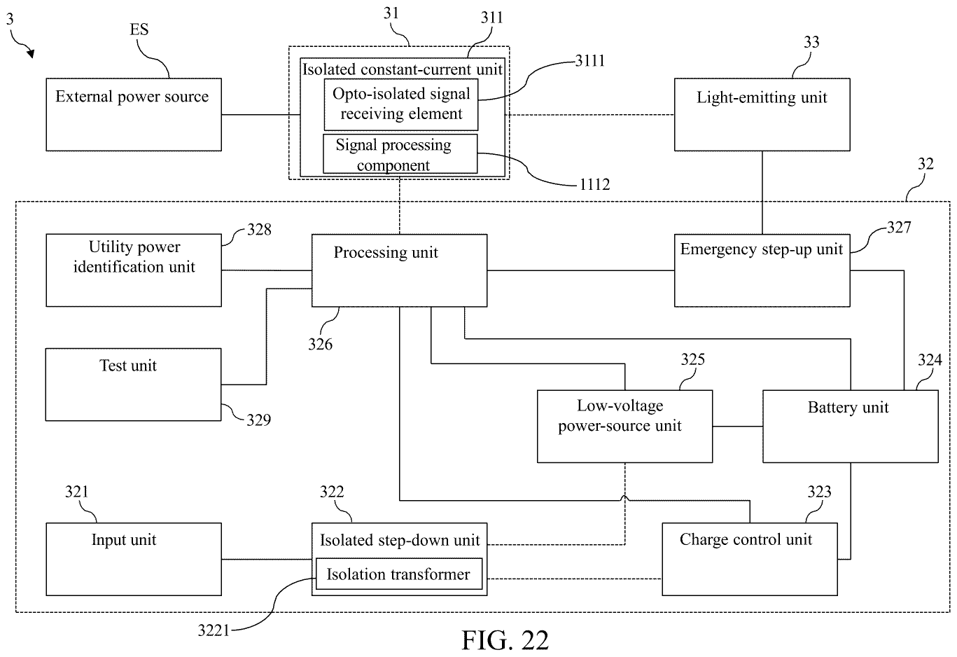

Please refer to FIG. 22, which is a block diagram of a circuit structure of a lighting device having an emergency lighting function in accordance with an eleventh embodiment of the disclosure. As shown in FIG. 22, the lighting device 3 includes a light emitting module 33, a main lighting power-supply module 31, and an emergency lighting power-supply module 32.

The light emitting module 33 may include one or more LEDs. The main lighting power-supply module 31 includes an isolated constant-current unit 311. The emergency lighting power-supply module 32 includes an input unit 321, an emergency step-up unit 327, a battery unit 324, a charge control unit 323, an isolated step-down unit 322, a processing unit 326, a low-voltage power-source unit 325, and a utility power identification unit 328.

The above components are similar to those in the previous embodiments and will not be further described. The difference between this embodiment and the previous embodiments is that the emergency lighting power-supply module 32 of this embodiment further includes a test unit 329.

The test unit 329 is connected to the processing unit 326 and is used to control the processing unit 326 to execute a transportation mode or an installation test mode. The test unit 329 may be a button, a knob, or other similar components. The processing unit 326 controls the battery unit 324 to enter a static state in the transportation mode. The test unit 329 may generate one or more square waves Ws. When the processing unit 326 detects the square waves Ws, the processing unit 326 determines whether the number of square waves Ws reaches a preset number, and upon determining that the preset number is reached, the processing unit 326 further determines whether the square waves Ws are continuous and have the same length. When the processing unit 326 determines that the square waves Ws are continuous and have the same length, the processing unit 326 executes the transportation mode.

In the installation test mode, the processing unit 326 turns off the isolated constant-current unit 311 and activates the emergency step-up unit 327 to drive the light emitting module 33 to perform an emergency lighting function test. After completion of the emergency lighting function test (such as after a preset time), the emergency lighting function is stopped.

Thus, in the transportation mode, the processing unit 326 controls the battery unit 324 to enter the static state, allowing the battery unit 324 to operate in a static low-power operating mode to prevent battery degradation. Therefore, the lighting device 3 can properly perform its emergency lighting function.

Additionally, in the installation test mode, the processing unit 326 turns off the isolated constant-current unit 311 and activates the emergency step-up unit 327 to drive the light emitting module 33 to perform an emergency lighting function test. Therefore, the user can quickly test whether the emergency lighting function of the lighting device 3 is normal during installation without waiting for an actual power failure, thus improving installation efficiency. Accordingly, the installation cost of the lighting device 3 can be significantly reduced.

The embodiment just exemplifies the disclosure and is not intended to limit the scope of the disclosure; any equivalent modification and variation according to the spirit of the disclosure is to be also included within the scope of the following claims and their equivalents.

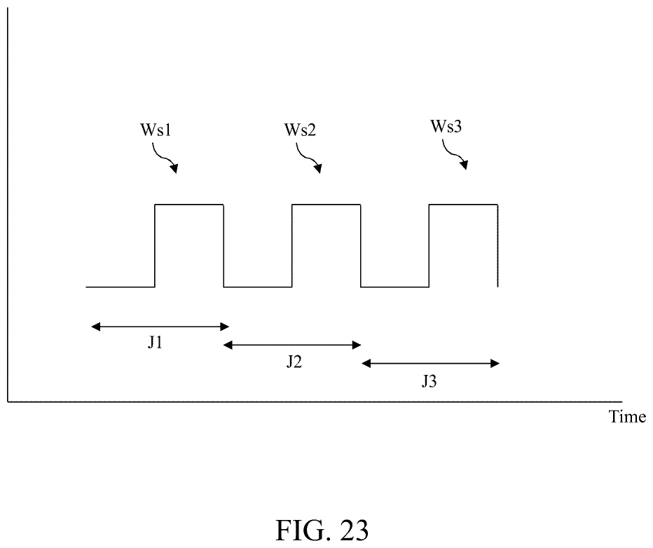

Please refer to FIG. 23, which is a first schematic view of a square wave generated by a test unit of the lighting device having the emergency lighting function in accordance with the eleventh embodiment of the disclosure. As shown in FIG. 23, the test unit 329 may control the processing unit 326 to perform the transportation mode. In this embodiment, the test unit 329 is a button, and the preset number is three (which may be adjusted according to actual requirements). By pressing the test unit 329 once, a square wave Ws may be generated (where a low-level signal is generated when the test unit 329 is pressed, and a high-level signal is generated when the test unit 329 is released). When the processing unit 326 detects the square waves Ws1, Ws2, and Ws3, the processing unit 326 determines whether the number of the square waves Ws1, Ws2, and Ws3 reaches three. At the same time, when the processing unit 326 determines that the above square waves Ws1, Ws2, and Ws3 reach three, the processing unit 326 further determines whether the square waves Ws1, Ws2, and Ws3 are continuous and whether they have the same length. The length of the square wave Ws1 is J1. The length of the square wave Ws2 is J2. The length of the square wave Ws3 is J3. When the processing unit 326 determines that the square waves Ws1, Ws2, and Ws3 are continuous and have the same length (J1=J2=J3), the processing unit 326 performs the transportation mode.

The embodiment just exemplifies the disclosure and is not intended to limit the scope of the disclosure; any equivalent modification and variation according to the spirit of the disclosure is to be also included within the scope of the following claims and their equivalents.

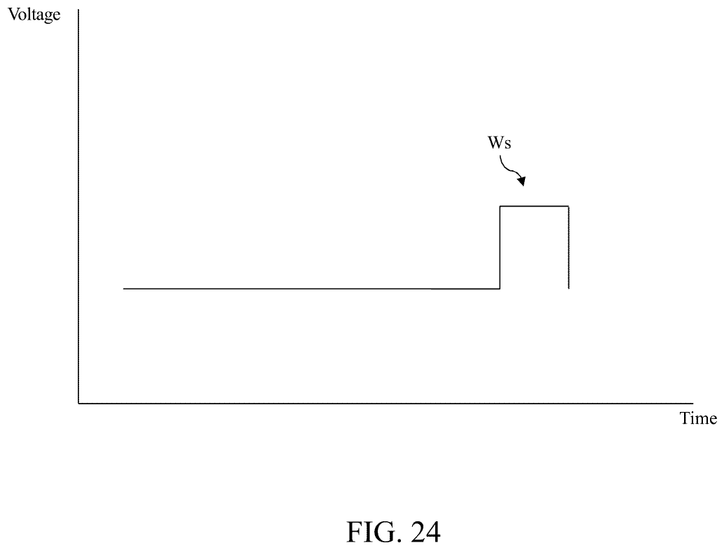

Please refer to FIG. 24, which is a second schematic view of the square wave generated by the test unit of the lighting device having the emergency lighting function in accordance with the eleventh embodiment of the disclosure. As shown in FIG. 24, the test unit 329 may control the processing unit 326 to perform the installation test mode. By long-pressing the test unit 329 once, a square wave Ws may be generated. When the processing unit 326 detects that the square wave Ws is generated by the long-press operation of the test unit 329, the test unit 329 controls the processing unit 326 to perform the installation test mode.

The embodiment just exemplifies the disclosure and is not intended to limit the scope of the disclosure; any equivalent modification and variation according to the spirit of the disclosure is to be also included within the scope of the following claims and their equivalents.

Currently available emergency lighting devices lack effective isolated power-source designs, and therefore their safety still requires further improvement. In addition, currently available emergency lighting devices often suffer from leakage-induced losses, preventing them from properly performing emergency lighting functions. By contrast, by contrast, according to one embodiment of the disclosure, the lighting device includes a lighting emitting module, a main lighting power-supply module, and an emergency lighting power-supply module. The main lighting power-supply module includes an isolated constant-current unit and is connected to the light emitting module and an external power source. The emergency lighting power-supply module includes an emergency step-up unit, a battery unit, a charge control unit, an isolated step-down unit, and an input unit. The emergency step-up unit is connected to the light emitting module. The battery unit is connected to the emergency step-up unit. The charge control unit is connected to the battery unit. The isolated step-down unit is connected to the charge control unit. The input unit is connected to the isolated step-down unit. The isolated constant-current unit includes an opto-isolated signal receiving element, a signal processing element, and a constant-current circuit. The isolated step-down unit includes an isolation transformer and a step-down converter. Through the isolated circuit design described above, the main lighting power-supply module can be isolated from the emergency lighting power-supply module, which can significantly enhance the safety of the lighting device.

According to one embodiment of the disclosure, the emergency lighting power-supply module of the lighting device further includes a processing unit and a test unit. The processing unit is connected to the emergency step-up unit, the battery unit, and the charge control unit. The processing unit communicates with the main lighting power-supply module. The test unit is connected to the processing unit and can control the processing unit to execute a transportation mode. In the transportation mode, the processing unit controls the battery unit into a static state such that the battery unit enters a static low-power operating mode to prevent energy loss. Therefore, the lighting device can properly perform the emergency lighting function.

Also, according to one embodiment of the disclosure, the test unit of the emergency lighting power-supply module of the lighting device can also control the processing unit to execute an installation test mode. In the installation test mode, the processing unit turns off the isolated constant-current unit and activates the emergency step-up unit to drive the light emitting module to perform an emergency lighting function test. Thus, the user may quickly test whether the emergency lighting function of the lighting device is operating properly during installation without waiting for an actual power failure, thereby improving installation efficiency. Accordingly, the installation cost of the lighting device can be significantly reduced.

Further, according to one embodiment of the disclosure, the test unit of the emergency lighting power-supply module of the lighting device generates one or more square waves. When the processing unit detects the above square waves, the processing unit determines whether the number of the square waves reaches a preset number, and when the number reaches the preset number, determines whether the square waves are continuous and have the same length. When the processing unit determines that the square waves are continuous and have the same length, the processing unit executes the transportation mode. Through the determination mechanism described above, the processing unit can accurately determine whether the test unit has been properly operated to execute the transportation mode or whether an accidental collision has caused accidental triggering, thereby preventing the lighting device from being mistakenly activated during transportation.

Moreover, according to one embodiment of the disclosure, the emergency lighting power-supply module of the lighting device further includes a utility power identification unit. The utility power identification unit is connected to the processing unit and is used to generate an identification signal. The processing unit executes a charging mode or an emergency mode according to the identification signal. In the charging mode, the processing unit activates the charge control unit to charge the battery unit. In the emergency mode, the processing unit activates the emergency step-up unit to drive the light emitting module to perform an emergency lighting function. Through the mechanism described above, the lighting device can properly execute the charging mode to charge the battery unit so as to make sure that the battery unit has sufficient power when the emergency mode is performed. Therefore, the lighting device can meet actual requirements.

Furthermore, according to one embodiment of the disclosure, the lighting device has a simple design and can achieve the desired effects without significantly increasing cost. Therefore, the safety of the lighting device can also be significantly improved. Accordingly, the lighting device can achieve high practicality and meet the requirements of various applications.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is

1. An emergency lighting device having an emergency test function, comprising:
an emergency test switch;
an input circuit having a first pin, a second pin, a third pin, and a fourth pin, wherein the first pin is connected to a live-wire output terminal of an external power source via a main switch, the second pin is connected to the live-wire output terminal, the third pin is connected to a neutral-wire output terminal of the external power source via the emergency test switch, and the fourth pin is connected to the neutral-wire output terminal;
a processing circuit connected to the input circuit;
an emergency circuit connected to the processing circuit; and
a load connected to the emergency circuit.

2. The emergency lighting device having the emergency test function as claimed in claim 1, wherein the input circuit is configured to drive the load to perform a normal lighting mode when the external power source is in a normal state and the main switch is turned on, and the processing circuit is configured to control the emergency circuit to enter a charging state.

3. The emergency lighting device having the emergency test function as claimed in claim 1, wherein the processing circuit is configured to receive an emergency test signal when the emergency test switch is operated in a preset operation mode, and to perform an emergency test mode to control the emergency circuit to activate the load.

4. The emergency lighting device having the emergency test function as claimed in claim 3, wherein the preset operation mode is defined as the emergency test switch remaining in an off state for a preset duration.

5. The emergency lighting device having the emergency test function as claimed in claim 1, further comprises a mode control switch and a mode control circuit, wherein the mode control circuit is connected to the processing circuit, and the mode control switch is connected to the mode control circuit, wherein the mode control switch is configured to control the mode control circuit to generate a mode control signal so as to control the processing circuit to enter a transportation mode, and the processing circuit is configured to enter a sleep state in the transportation mode.

6. The emergency lighting device having the emergency test function as claimed in claim 1, wherein the emergency circuit comprises a rechargeable battery and a charge control circuit connected to each other, and the charge control circuit is configured to perform charge control on the rechargeable battery.

7. The emergency lighting device having the emergency test function as claimed in claim 1, wherein the rechargeable battery comprises a plurality of battery elements arranged in a pyramid-shaped structure.

8. The emergency lighting device having the emergency test function as claimed in claim 7, wherein the battery elements are connected to the charge control circuit via a plurality of metal conductive sheets, and the battery elements and the charge control circuit are fixed to each other via the metal conductive sheets.

9. The emergency lighting device having the emergency test function as claimed in claim 1, wherein the charge control circuit covers a gap between at least two of the battery elements.

10. An emergency lighting device having an emergency test function, comprising:
an emergency test switch;
an input circuit having a first pin, a second pin, a third pin, and a fourth pin, wherein the first pin is connected to a live-wire output terminal of an external power source via a main switch, the second pin is connected to a neutral-wire output terminal of the external power source, the third pin is connected to the live-wire output terminal, and the fourth pin is connected to the neutral-wire output terminal via the emergency test switch;
a processing circuit connected to the input circuit;
an emergency circuit connected to the processing circuit; and
a load connected to the emergency circuit.

11. The emergency lighting device having the emergency test function as claimed in claim 10 wherein the input circuit is configured to drive the load to perform a normal lighting mode when the external power source is in a normal state and the main switch is turned on, and the processing circuit is configured to control the emergency circuit to enter a charging state.

12. The emergency lighting device having the emergency test function as claimed in claim 10 wherein the processing circuit is configured to receive an emergency test signal when the emergency test switch is operated in a preset operation mode, and to perform an emergency test mode to control the emergency circuit to activate the load.

13. The emergency lighting device having the emergency test function as claimed in claim 12 wherein the preset operation mode is defined as the emergency test switch remaining in an off state for a preset duration.

14. The emergency lighting device having the emergency test function as claimed in claim 10 further comprising a mode control switch and a mode control circuit, wherein the mode control circuit is connected to the processing circuit, and the mode control switch is connected to the mode control circuit, wherein the mode control switch is configured to control the mode control circuit to generate a mode control signal so as to control the processing circuit to enter a transportation mode, and the processing circuit is configured to enter a sleep state in the transportation mode.

15. The emergency lighting device having the emergency test function as claimed in claim 10 wherein the emergency circuit comprises a rechargeable battery and a charge control circuit connected to each other, and the charge control circuit is configured to perform charge control on the rechargeable battery.

16. The emergency lighting device having the emergency test function as claimed in claim 15 wherein the rechargeable battery comprises a plurality of battery elements arranged in a pyramid-shaped structure.

17. The emergency lighting device having the emergency test function as claimed in claim 16 wherein the battery elements are connected to the charge control circuit via a plurality of metal conductive sheets, and the battery elements and the charge control circuit are fixed to each other via the metal conductive sheets.

18. The emergency lighting device having the emergency test function as claimed in claim 16 wherein the charge control circuit covers a gap between at least two of the battery elements.
